(19) United States
(12) Patent Application Publication
(10) Pub. No.: US 2026/0016763 A1
(43) Pub. Date: Jan. 15, 2026

(54) LITHOGRAPHY APPARATUS AND METHOD FOR OPERATING THE SAME

(71) Applicant: TAIWAN SEMICONDUCTOR MANUFACTURING COMPANY, LTD., Hsinchu (TW)

(72) Inventors: Wei-Huai CHIU, Miaoli County (TW); Yu-Chi Tsai, Hsinchu County (TW); Fan-Chi Lin, Hsinchu (TW)

(73) Assignee: TAIWAN SEMICONDUCTOR MANUFACTURING COMPANY, LTD., Hsinchu (TW)

(21) Appl. No.: 18/767,396

(22) Filed: Jul. 9, 2024

(51) Int. Cl. G03F 9/00; G03F 7/00

(52) U.S. Cl. CPC G03F 9/7076; G03F 7/70716; G03F 9/7065; G03F 9/7084

(57) ABSTRACT

A lithography apparatus includes a substrate stage having a first region configured to hold a semiconductor substrate and a second region surrounding the first region; a light receiver structure over the second region of the substrate stage; a light source configured to provide an alignment light toward the second region of the substrate stage; a mask stage configured to secure a mask; and an optical module configured to direct an exposure light from the mask onto the semiconductor substrate.

### BACKGROUND

A lithography apparatus is a machine that applies a desired pattern onto a substrate. A lithography apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is via imaging onto a layer of radiation-sensitive material (resist) provided on the substrate. In general, a single substrate will contain a network of adjacent target portions that are successively patterned. Various alignment techniques have been developed to control the lithographic process to place device features accurately on the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a lithography apparatus according to some embodiments of the present disclosure.

FIG. 1B is schematic view of a portion of the lithography apparatus of FIG. 1A.

FIG. 2A is a schematic view of a light receiver structure according to some embodiments of the present disclosure.

FIG. 2B is schematic cross-sectional view of the light receiver structure of FIG. 2A.

FIG. 2C is a schematic view of a light sensing device of the light receiver structure of FIG. 2B.

FIG. 2D is a top view of a photosensitive device layer of the light sensing device of FIG. 2C.

FIG. 2E is a top view of a color filter layer of the light sensing device of FIG. 2C.

FIG. 3 is a schematic view of a light sensing device according to some embodiments of the present disclosure.

FIGS. 4A and 4B show light rays of light sources according to some embodiments of the present disclosure.

FIG. 5A shows an inspection condition according to some embodiments of the present disclosure.

FIG. 5B is a result of the inspection condition of FIG. 5A.

FIG. 6A shows an inspection condition according to some embodiments of the present disclosure.

FIG. 6B is a result of the inspection condition of FIG. 6A.

FIG. 7A shows an inspection condition according to some embodiments of the present disclosure.

FIG. 7B is a result of the inspection condition of FIG. 7A.

FIG. 8A shows a Mueller matrix representing behavior between a light source and a light receiver.

FIG. 8B shows a Jones matrix calculating behavior between a light source and a light receiver.

FIG. 9 is a method for wafer stage alignment in a lithography apparatus.

FIG. 10 is a method for wafer stage alignment in a lithography apparatus.

FIG. 11A shows an inspection condition according to some embodiments of the present disclosure.

FIG. 11B is a result of the inspection condition of FIG. 11A.

FIG. 12A shows an inspection condition according to some embodiments of the present disclosure.

FIG. 12B is a result of the inspection condition of FIG. 12A.

FIG. 13A shows an inspection condition according to some embodiments of the present disclosure.

FIG. 13B is a result of the inspection condition of FIG. 13A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

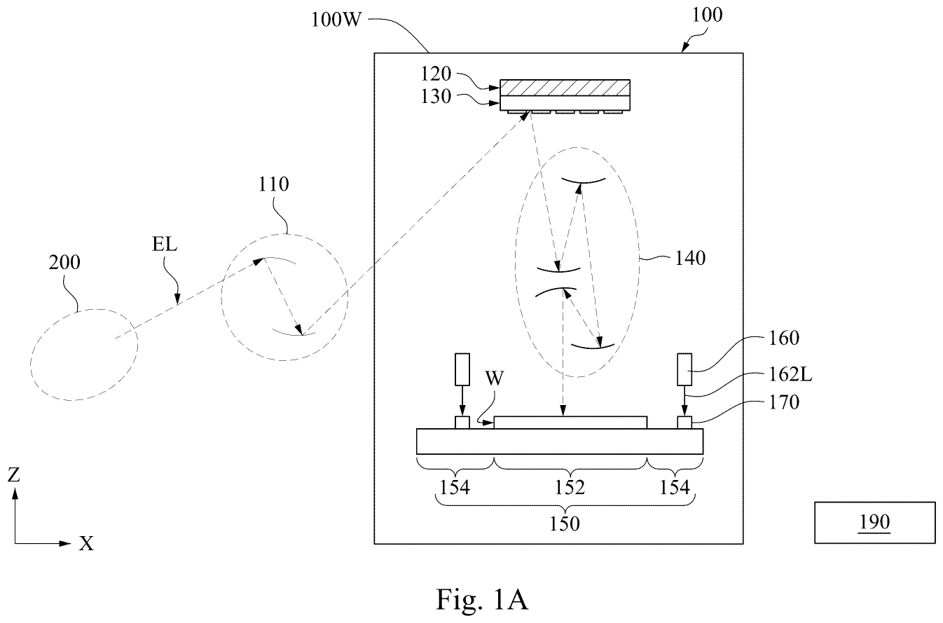

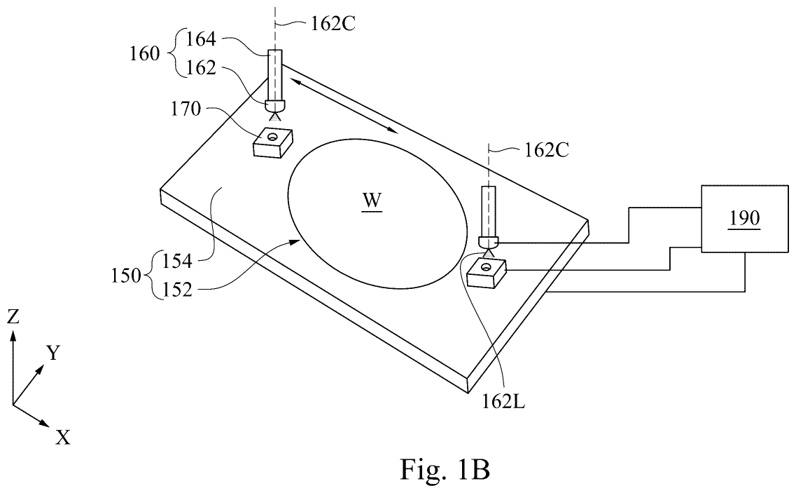

FIG. 1A is a schematic view of a lithography apparatus 100 according to some embodiments of the present disclosure. FIG. 1B is schematic view of a portion of the lithography apparatus 100 of FIG. 1A. The lithography apparatus 100 may also be referred to as a scanner that is operable to perform lithography exposing processes with respective radiation source and exposure mode. The lithography apparatus 100 provide an exposure light EL to expose a resist layer by the exposure light EL. In some embodiments, the exposure light EL provided by the lithography apparatus 100 is an extreme ultraviolet (EUV) radiation, and the resist layer is a material sensitive to the EUV radiation. In such embodiments, the EUV lithography apparatus 100 employs a radiation source 200 to generate EUV radiation, such as EUV radiation having a wavelength ranging between about 1 nm and about 100 nm. In certain examples, the EUV radiation has a wavelength range centered at about 13.5 nm. Accordingly, the radiation source 200 is also referred to as an EUV radiation source 200. In some alternative embodiments, the exposure light EL provided by the lithography apparatus 100 is ultraviolet (UV) radiation or deep ultraviolet (DUV) radiation, not limited to the EUV radiation.

The lithography apparatus 100 also employs an illuminator 110. In some embodiments, the illuminator 110 includes various reflective optics such as a single mirror or a mirror system having multiple mirrors in order to direct the EUV exposure light EL from the radiation source 200 onto a mask stage 120, particularly to a mask 130 secured on the mask stage 120.

The lithography apparatus 100 also includes the mask stage 120 configured to secure the mask 130. In some embodiments, the mask stage 120 includes an electrostatic chuck (e-chuck) used to secure the mask 130. In this context, the terms mask, photomask, and reticle are used interchangeably. In the present embodiments, the lithography apparatus 100 is an EUV lithography system, and the mask 130 is a reflective mask. One exemplary structure of the mask 130 includes a substrate with a low thermal expansion material (LTEM). For example, the LTEM may include TiO₂ doped SiO2, or other suitable materials with low thermal expansion. The mask 130 includes a reflective multi-layer deposited on the substrate. The reflective multi-layer includes plural film pairs, such as molybdenum-silicon (Mo/Si) film pairs (e.g., a layer of molybdenum above or below a layer of silicon in each film pair). Alternatively, the reflective multi-layer may include molybdenum-beryllium (Mo/Be) film pairs, or other suitable materials that are configurable to highly reflect the EUV exposure light EL. The mask 130 may further include a capping layer, such as ruthenium (Ru), disposed on the reflective multi-layer for protection. The mask 130 further includes an absorption layer, such as a tantalum boron nitride (TaBN) layer, deposited over the reflective multi-layer. The absorption layer is patterned to define a layer of an integrated circuit (IC). The mask 130 may have other structures or configurations in various embodiments.

The lithography apparatus 100 also includes a projection optics module (or projection optics box (POB)) 140 for imaging the pattern of the mask 130 onto a semiconductor substrate W secured on a substrate stage (or a wafer stage or a chuck) 150 of the lithography apparatus 100. The POB 140 includes reflective optics in the present embodiments. The exposure light EL that is directed from the mask 130 and carries the image of the pattern defined on the mask 130 is collected by the POB 140. The illuminator 110 and the POB 140 may be collectively referred to as an optical module of the lithography apparatus 100.

In the present embodiments, the semiconductor substrate W is a semiconductor wafer, such as a silicon wafer or other type of wafer to be patterned. The semiconductor substrate W is coated with a resist layer sensitive to the EUV exposure light EL in the present embodiments. Various components including those described above are integrated together and are operable to perform lithography exposing processes. In some embodiments, the EUV exposure light EL is controlled to incident onto the semiconductor substrate W along a direction Z. For normal incidence, a top surface of the substrate stage 150 is controlled to be parallel with a plane of directions X and Y. The directions X, Y, and Z are orthogonal to each other. The substrate stage 150 may has a first region 152 configured to support/hold the semiconductor substrate W and a second region 154 surrounding the first region 152.

In some embodiments of the present disclosure, the lithography apparatus 100 includes a light source structure 160 and a light receiver structure 170. In the present embodiments, the light receiver structure 170 is disposed on the top surface of the second region 154 of the substrate stage 150, for example, by being mounted on the top surface of the second region 154 of the substrate stage 150 or attached to the top surface of the second region 154 of the substrate stage 150. The light source structure 160 may include a light source 162 and a holder 164 configured to hold the light source 162. The light source 162 is configured to provide an alignment light 162L toward the second region 154 of the substrate stage 150 (e.g., toward the light receiver structure 170) along its optical axis 162C, which is substantially parallel with the direction Z. The alignment light 162L provided by the light source 162 may have a wide-band wavelength. For example, the light source 162 is a broadband light source (e.g., white light-emitting diode (LED)) or a multi-channel mixed laser. For example, a coherent length of the alignment light 162L may be less than about 20 micrometer, less than about 10 micrometers, or even less than about 5 micrometers. In some alternative embodiments, the light source 162 is monochromatic light source, such as a laser. The light source 162 can provide the alignment light 162L with different wavelengths, different orders, and light energy, which may be beneficial for bring information correlated to alignment condition of the substrate stage 150. The alignment light 162L may not substantially expose the resist layer over the semiconductor substrate W. In some embodiments, the alignment light 162L has a peak wavelength different from a peak wavelength of the exposure light EL. For example, a peak wavelength of the exposure light EL may be extreme ultraviolet (EUV) light, while a peak wavelength of the alignment light 162L may be in visible light spectrum or the deep ultraviolet light (DUV). In some embodiments, the lithography apparatus 100 has a wall 100W surrounding the mask stage 120, the POB 140, the substrate stage 150, the light source structure 160, and the light receiver structure 170.

Optical axis is an imaginary line passing through both the centers of curvatures of the optical surfaces of a lens or mirror. Optical axis may be an optical centerline for all the centers of an optical element(s) of an optical system. The optical axis is also the reference axis in which a particular degree of rotational symmetry is defined for an optical system. The path of a light ray along this axis is perpendicular to the surfaces and, as such, will be substantially unchanged.

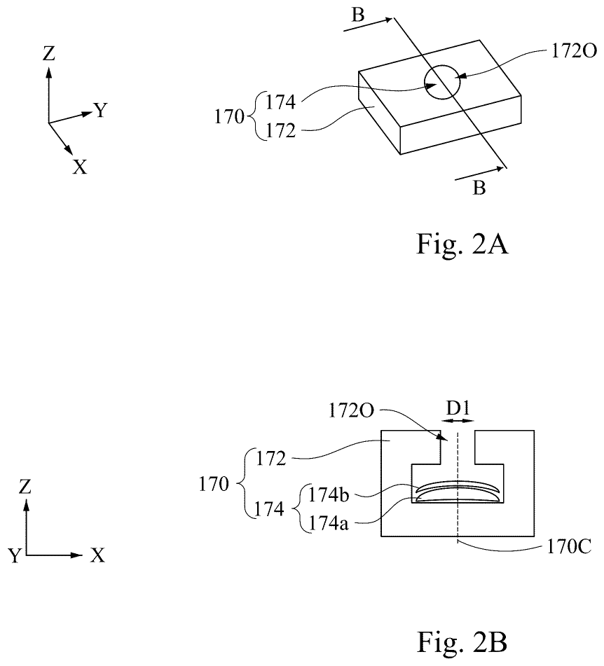

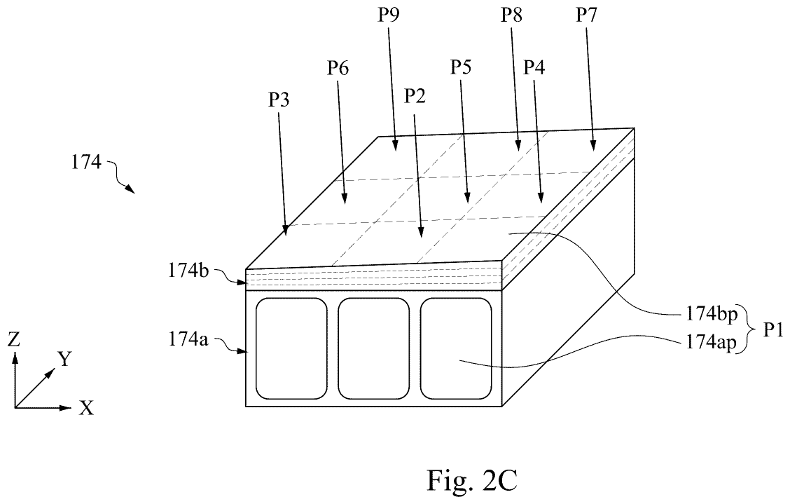

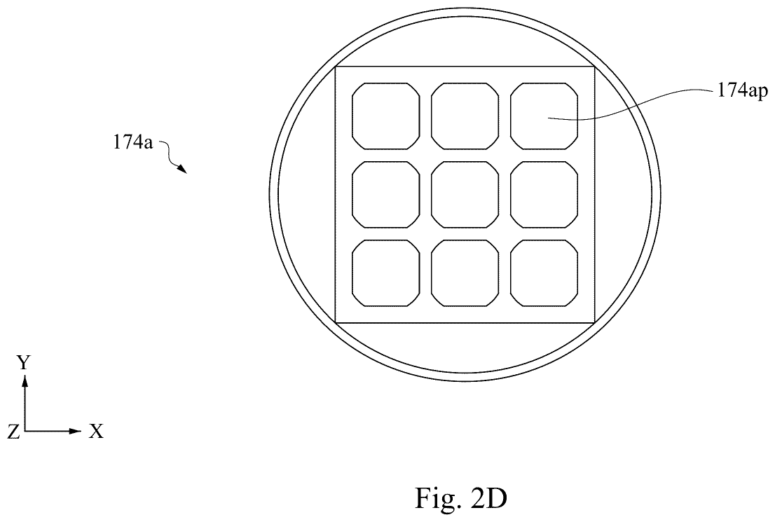

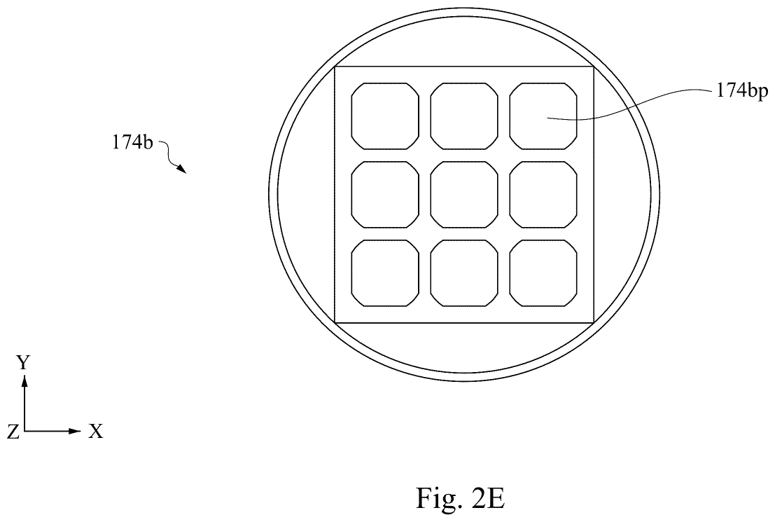

FIG. 2A is a schematic view of a light receiver structure 170 according to some embodiments of the present disclosure. FIG. 2B is schematic view of a cross-sectional view of the light receiver structure 170 of FIG. 2A. The light receiver structure 170 may include a shell 172 and a light sensing device 174. The shell 172 surrounds the light sensing device 174. The shell 172 may be made of an opaque or reflective material that would block light, for example, by absorbance or reflection, from passing itself. The shell 172 may be referred to as a light shielding box. In some embodiments, a portion of the shell 172 between the light sensing device 174 and the light source structure 160 may be referred to as a light shielding plate. The shell 172 has an opening 172O facing away from the substrate stage 150 and exposing the light sensing device 174. The light receiver structure 170 may have an imaginary center line 170C extending from a center of the opening 172O to the light receiver structure 170 along the direction Z. In some embodiments, the opening 172O may serve as an aperture stop in an inspection system including the light source structure 160 and the light receiver structure 170. By controlling the size of the opening 172O of the shell 172, the amount of light reaching the light sensing device 174 can be adjusted, thereby changing the alignment resolution accordingly. In some alternative embodiments, an aperture stop can be used, and the shell 172 may be omitted.

In the present embodiments, the opening 172O is illustrated as having a circular shape, in which a length of the opening 172O along the direction X is substantially the same as a length of the opening 172O along the direction Y. In some alternative embodiments, the opening 172O may be a slit having elongated shape. For example, a length of the opening 172O along the direction X is greater than a length of the opening 172O along the direction Y. Alternatively, a length of the opening 172O along the direction Y is greater than a length of the opening 172O along the direction X. In some other embodiments, the opening 172O may have a rectangular shape, a triangular shape, an oval shape the like, or the combination thereof.

FIG. 2C is a schematic view of the light sensing device 174 of the light receiver structure 170 of FIG. 2B. FIG. 2D is a top view of a photosensitive device layer 174a of the light sensing device 174 of FIG. 2C. FIG. 2E is a top view of a color filter layer 174b of the light sensing device 174 of FIG. 2C. Reference is made to FIGS. 2C-2E. The light sensing device 174 may include a photosensitive device layer 174a and a color filter layer 174b overlying the photosensitive device layer 174a.

The photosensitive device layer 174a may include an array of photosensitive regions 174ap. The photosensitive regions 174ap may also be referred to as photosensitive pixels in some embodiments. The photosensitive device layer 174a may be an image sensor, such as a charge-coupled device (CCD) or a complementary metal-oxide-semiconductor (CMOS) image sensor. In some embodiments, the photosensitive regions 174ap may be arranged along a plane, which is substantially parallel with a top surface of the substrate stage 150 (e.g., the plane of the direction X and Y).

In some embodiments, the color filter layer 174b is a linear variable color filter layer, and different portions 174bp of the color filter layer 174b overlying the photosensitive regions 174ap has different transmittance spectrum/wavelengths. These transmittance spectrum/wavelengths may be in visible light spectrum, longer than the exposure light EL. For example, the portions 174bp of the color filter layer 174b allow light having different wavelengths (e.g., about 405 nanometers, about 425 nanometers, about 450 nanometers, about 475 nanometers, about 515 nanometers, about 550 nanometers, about 555 nanometers, about 600 nanometers, about 640 nanometers, about 690 nanometers, about 74 nanometers, about 855, or any other suitable values) to pass themself, respectively. Sometimes, the portions 174bp of the color filter layer 174b allow light having different wavelengths of about 400 nanometers, about 500 nanometers, about 600 nanometers, to pass themself, respectively. Stated differently, each portion 174bp of the linear variable color filter layer 174b may block/filter out unwanted wavelength of the light from the light source 162 and only transmit specific feature wavelengths of the light from the light source 162 to the photosensitive regions 174ap.

The color filter layer 174b has more than three portions 174bp having different transmittance spectrum/wavelengths therein. For example, there are nine portions 174bp in the illustrated figures. In some embodiments, a number of the portions 174bp having different transmittance spectrum/wavelengths from each other may be in a range from about 3 to about 256, such as from about 9 to about 128.

The light receiver structure 170 may be referred to as a multi-channel color receiver that can send multi-channels value, in which a channel value can be represented by one of plural pixels (e.g., pixels P1-P9). Each of the pixels P1-P9 may include a portion 174bp of the color filter layer 174b and a photosensitive region 174ap therebelow. The pixels P1-P9 can detect light of different peak wavelengths depending on the transmittance spectrum/wavelengths of the portion 174bp of the color filter layer 174b thereof. The peak wavelengths of the pixels P1-P9 may be different from each other. In some alternative embodiments, a channel value can be represented by two or more of the pixels (e.g., pixels P1-P9). The multi-channel color receiver can detect a wide-band wavelength.

The light sensing device 174 may include any suitable optical films, such as a film of micro-lens array, a Fresnel lens film, the like, or the combination thereof. The optical film(s) can be located between the photosensitive device layer 174a and the color filter layer 174b or on a side of the color filter layer 174b opposite to the photosensitive device layer 174a.

Reference is made to FIGS. 1A, 1B, 2A, and 2B. The light receiver structure 170 can send multi-channels value for quantify alignments position. The lithography apparatus 100 may include a controller 190 electrically coupled with the photosensitive device layer 174a, the light source 162, and optionally the substrate stage 150. Through the configuration, by using the light sensing device 174 to detect a condition of the alignment light 162L provided by the light source 162 through the shell 172, a detection result may reveal a status of the substrate stage 150. For example, the detection result may reveal a tilt of the top surface of the substrate stage 150 or a shift of the substrate stage 150. Thus, a tilt angle or a position of the substrate stage 150 can be adjusted according to the detection result manually or automatically (e.g., by a controller 190), thereby facilitating the wafer stage alignment.

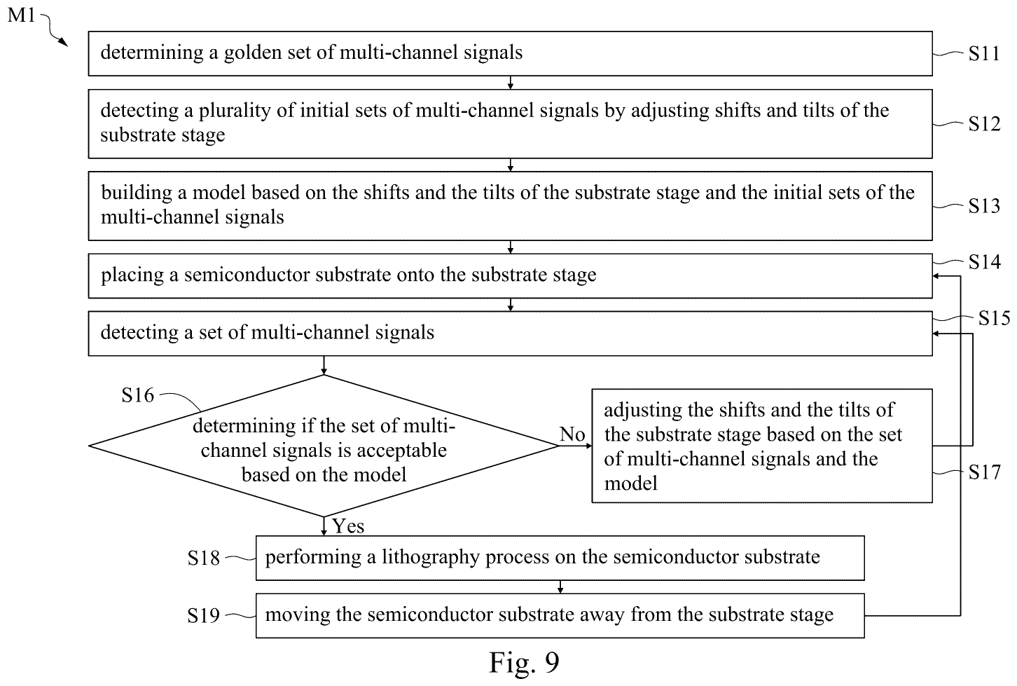

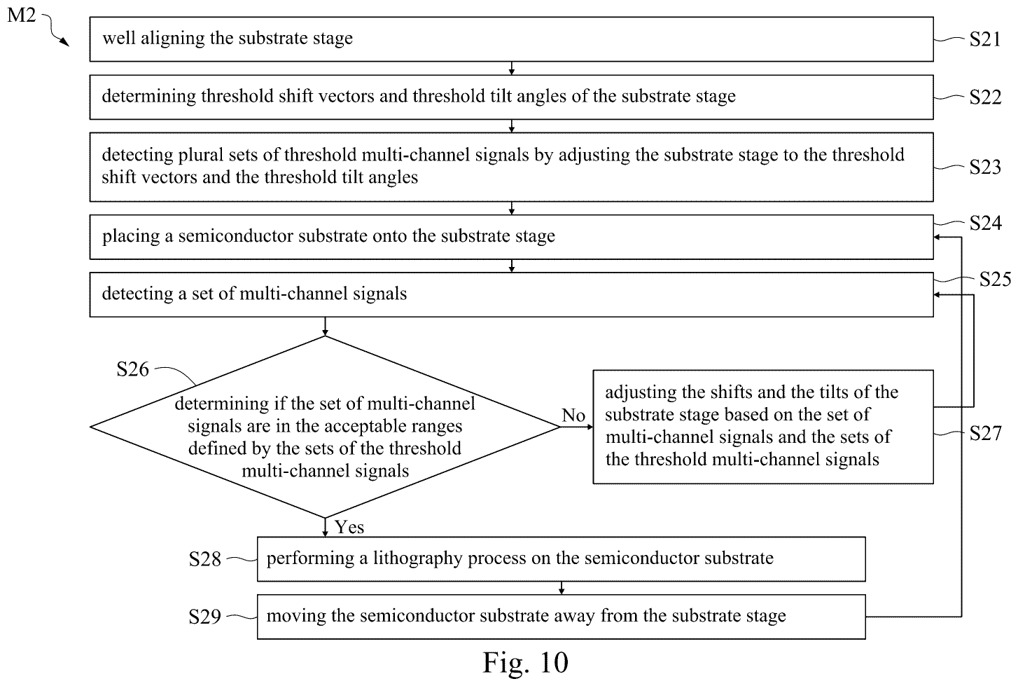

In some embodiments, the controller 190 may be surrounded by the wall 100W or outside the wall 100W. The controller 190 may include a computer-readable storage medium and a processor coupled to the computer-readable storage medium. The processor is configured to execute programming instructions stored in the computer-readable storage medium. In some embodiments, the computer-readable storage medium stores programming instructions that performs various steps of the methods in FIGS. 9 and 10 discussed later. The controller 190 controls the operations of the photosensitive device layer 174a, the light source 162, and optionally the substrate stage 150 by using the processor reading out and executing the program stored in the storage medium. The program may be one that has been stored in the computer-readable storage medium, or may be one that has been installed to the storage medium of the controller 190. In some embodiments, the controller 190 may include processors, central processing units (CPU), multi-processors, distributed processing systems, application specific integrated circuits (ASIC), or the like.

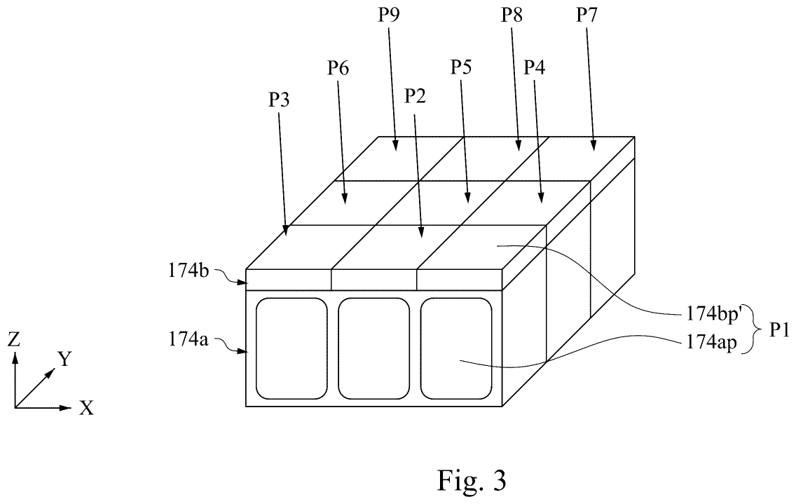

FIG. 3 is a schematic view of a light sensing device 174 according to some embodiments of the present disclosure. Details of the present embodiments are similar to those illustrated in the embodiments of FIGS. 2C-2E, except that the color filter layer 174b may include an array of color filters 174bp′ respectively overlying the photosensitive regions 174ap, in which each of the color filters 174bp′ has different transmittance spectrum/wavelengths. For example, the color filters 174bp′ allow alignment light 162L having different wavelengths (e.g., about 405 nanometers, about 425 nanometers, about 450 nanometers, about 475 nanometers, about 515 nanometers, about 550 nanometers, about 555 nanometers, about 600 nanometers, about 640 nanometers, about 690 nanometers, about 74 nanometers, about 855, or any other suitable values) to pass themself, respectively. Sometimes, the color filters 174bp′ allow light having different wavelengths of about 400 nanometers, about 500 nanometers, about 600 nanometers, to pass themself, respectively. Stated differently, each color filter 174bp′ may block/filter out unwanted wavelength of the alignment light 162L from the light source 162 and only transmit specific feature wavelengths of the alignment light 162L from the light source 162 to the photosensitive regions 174ap.

The color filter layer 174b has more than three color filters 174bp′ having different transmittance spectrum/wavelengths therein. For example, there are nine color filters 174bp′ in the illustrated figures. In some embodiments, a number of the color filters 174bp′ having different transmittance spectrum/wavelengths from each other may be in a range from about 3 to about 256, such as from about 9 to about 128.

The light receiver structure 170 may be referred to as a multi-channel color receiver that can send multi-channels value, in which a channel value can be represented by one of plural pixels (e.g., pixels P1-P9). Each of the pixels P1-P9 may include a color filter 174bp′ and a photosensitive region 174ap therebelow. The pixels P1-P9 can detect light of different peak wavelengths depending on the transmittance spectrum/wavelengths of the color filter 174bp′ thereof. The peak wavelengths of the pixels P1-P9 may be different from each other. In some alternative embodiments, a channel value can be represented by two or more of the pixels (e.g., pixels P1-P9). The multi-channel color receiver can detect a wide-band wavelength. Other details of the present disclosure are similar to those illustrated in the embodiments of FIGS. 2C-2E, and thereto not repeated herein.

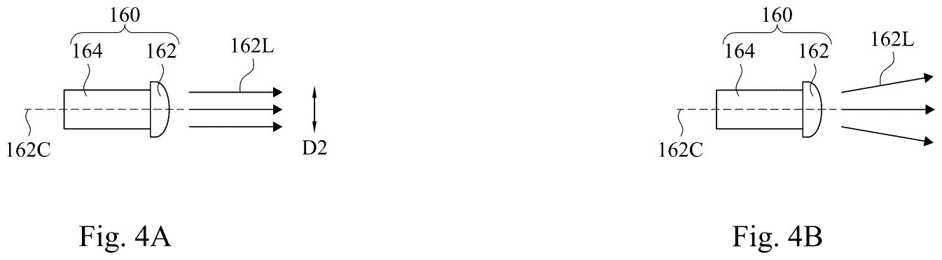

FIGS. 4A and 4B shows light rays of light sources 162 according to some embodiments of the present disclosure. In FIG. 4A, the alignment light 162L provided by the light source 162 may be parallel light. For example, rays of the alignment light 162L are parallel with each other. In some embodiments, a beam size of the alignment light 162L is greater than a size of the opening 172O of the shell 172. For example, a diameter D2 of the beam of the alignment light 162L is greater than the diameter D1 of the opening 172O of the shell 172.

In FIG. 4B, the alignment light 162L provided by the light source 162 may be divergent light. For example, the alignment light 162L emitted from the light source 162 may have a divergent angle in a range from about 0 degree to about 90 degrees, depending on whether a light emitted diode (LED) or a laser light is used.

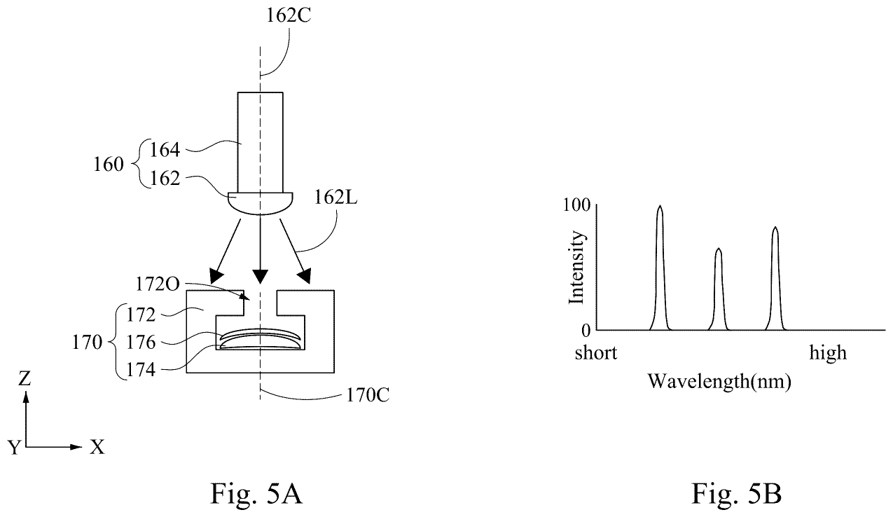

FIG. 5A shows an inspection condition according to some embodiments of the present disclosure. FIG. 5B is a result of the inspection condition of FIG. 5A. The optical axis 162C of the light source 162 is along the direction Z and aligned with a center line 170C of the light receiver structure 170. In the present embodiments, the light receiver structure 170 detects light of different colors, which means that the position of the substrate stage 150 is correct.

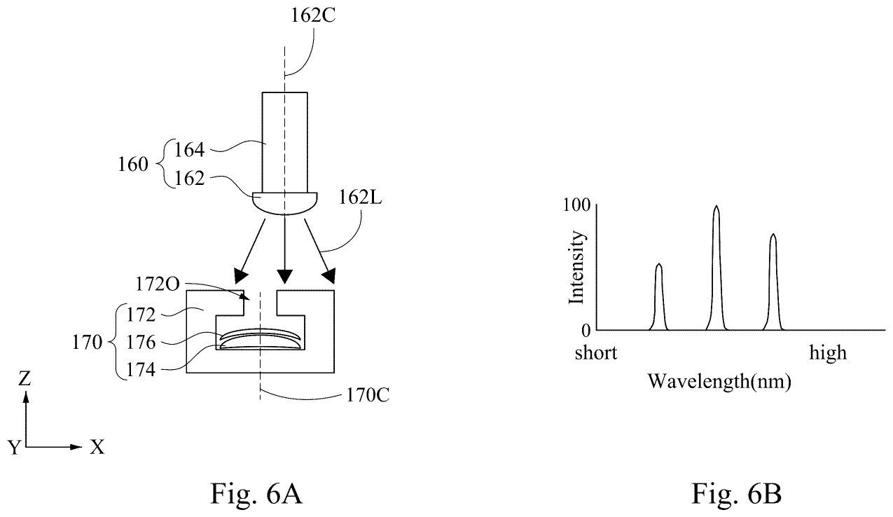

FIG. 6A shows an inspection condition according to some embodiments of the present disclosure. FIG. 6B is a result of the inspection condition of FIG. 6A. The optical axis 162C of the light source 162 is along the direction Z and misaligned with the center line 170C of the light receiver structure 170. Stated differently, the optical axis 162C of the light source 162 is shifted from the center line 170C of the light receiver structure 170. In the present embodiments, the light receiver structure 170 detects light of different colors, which indicates a shift of the substrate stage 150.

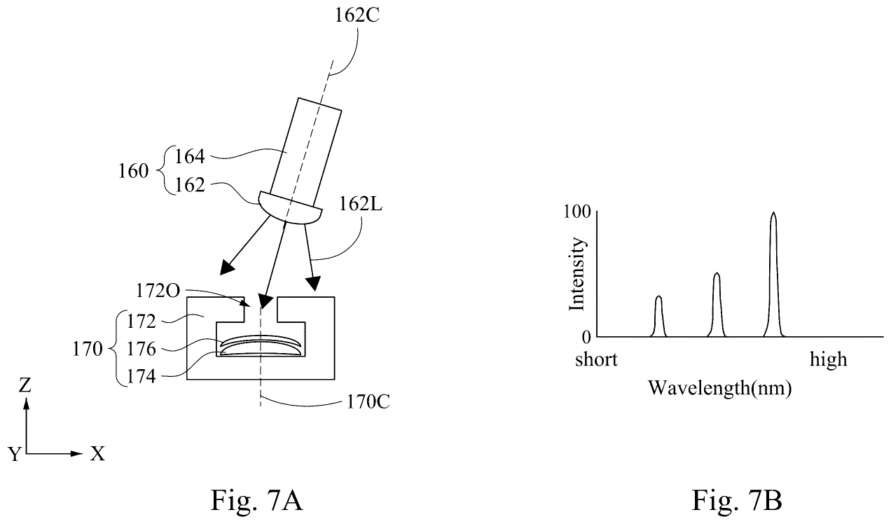

FIG. 7A shows an inspection condition according to some embodiments of the present disclosure. FIG. 7B is a result of the inspection condition of FIG. 7A. The optical axis 162C of the light source 162 is tilted with respect to the direction Z. The optical axis 162C of the light source 162 may be aligned or misaligned with the center line 170C of the light receiver structure 170. In the present embodiments, the light receiver structure 170 detects light of different colors, which indicates a tilt of the substrate stage 150.

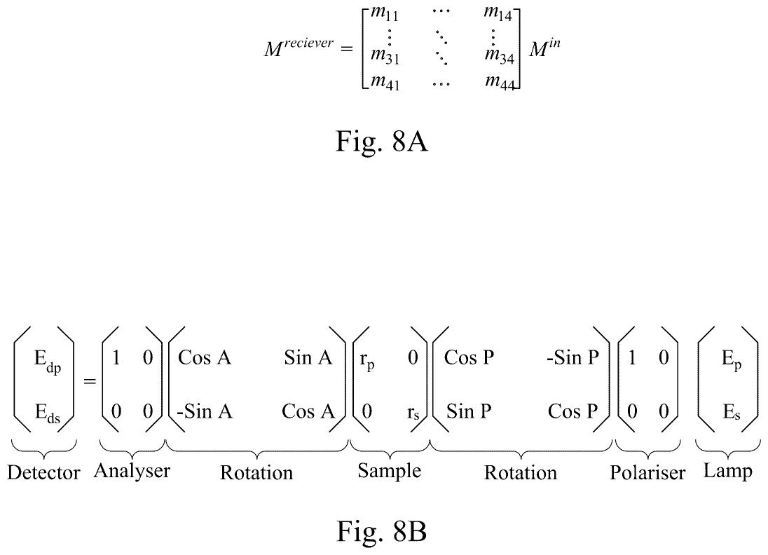

FIG. 8A shows a Mueller matrix representing behavior between a light source and a light receiver, such as the light source 162 and the light sensing device 174. m₁₁-m₄₄ are parameters of optical elements between the light source and the light receiver. M_{receiver} and Mᵢₙ are the Stokes vectors of the light received by the light receiver and the light emitted from the light source. FIG. 8B shows a Jones matrix calculating behavior between a light source and a light receiver. A and B are the angles of rotation. E_{dp} and E_{ds} are electric fields of light received by the light receiver (e.g., detector). Eₚ and Eₛ are electric fields of light emitted from the light source (e.g., lamp). Optical elements, such as analyzer, polarizer, sample, or the like (e.g., aperture) may be disposed between the light source and the light receiver. For example, rₚ and rₛ are parameters characterizing the sample. The Mueller matrix can be used to represent different relative positions (between the light source and the wafer platform), such that a determination regarding the wafer alignment can be made based on the calculation results of the Mueller matrix.

FIG. 9 is a method M1 for wafer stage alignment in a lithography apparatus 100. Reference is made to FIG. 9 and FIGS. 1A and 1B. The method M1 may include steps S11-S19. It is understood that additional steps may be provided before, during, and after the steps S11-S19 shown by FIG. 9, and some of the steps described below can be replaced or eliminated for additional embodiments of the method. The order of the operations/processes may be interchangeable.

The method M1 begins at step S11, where the controller 190 may determine a golden set of multi-channel signals. In some embodiments, the controller 190 may receive the golden set of the multi-channel signals from a datasheet provided by a manufacturer. In some embodiments, referring to FIGS. 1A and 1B, the controller 190 may control/move the substrate stage 150, such that that the surface of the substrate stage 150 is substantially parallel with the plane of the direction X and Y, and the substrate stage 150 is located at an ideal exposure position. The controller 190 may control the light source 162 provide the alignment light 162L toward the second region 154 of the substrate stage 150 (e.g., toward the light sensing device 174). And, the controller 190 may control the light sensing device 174 on the second region 154 of the substrate stage 150 to detect a set of multi-channel signals when the surface of the substrate stage 150 is substantially parallel with the plane of the direction X and Y and the substrate stage 150 is located at the ideal exposure position. This set of multi-channel signals is determined as the golden set of multi-channel signals. In some embodiments, the step S11 can be omitted.

The method M1 proceeds to step S12, where the controller 190 may control the substrate stage 150 to shift and/or tilt, for example, and the light sensing device 174 detect a plurality of initial sets of multi-channel signals under different shift and/or tilt status. For example, the controller 190 may control the substrate stage 150 to shift by a first shift vector and tilt by a first tilt angle, and the light sensing device 174 detect a first initial set of multi-channel signals under the first shift vector and the first tilt angle. Subsequently, the controller 190 may control the substrate stage 150 to shift by a second shift vector and tilt by a second tilt angle, and the light sensing device 174 detect a second initial set of multi-channel signals under the second shift vector and the second tilt angle. Then, the controller 190 may control the substrate stage 150 to shift by a third shift vector and tilt by a third tilt angle, and the light sensing device 174 detect a third initial set of multi-channel signals under the third shift vector and the third tilt angle. In the present embodiments, at least two of the first to third shift vectors may be different from each other, and/or at least two of the first to third tilt angles may be different from each other. For example, the first shift vector is different from the second shift vector, and/or the first tilt angle is different from the second tilt angle; the first shift vector is different from the third shift vector, and/or the first tilt angle is different from the third tilt angle; and the second shift vector is different from the third shift vector, and/or the second tilt angle is different from the third tilt angle.

The method M1 proceeds to step S13, where the controller 190 may build a model based on the shifts and the tilts of the substrate stage 150 and the initial sets of the multi-channel signals. For example, the first to third shift vectors, the first to third tilt angles, and first to third initial sets of the multi-channel signals are considered as training parameters for training a model. The trained model can be a trained artificial intelligence (AI), such as dynamic neural network, or a deep dynamic neural network. Such a neural network may comprise a network of perceptrons, or may be a hybrid neural network, a recurrent neural network. Alternatively, trained Al may be a trained support vector machine (SVM). The model can evaluate a wafer alignment status responsive to input parameters, e.g. detected sets of multi-channel signals. For example, the model is able to determine a tilt and/or shift of the substrate stage 150 from changes to the sets of multi-channel signals as described in one or more inputs. In some embodiments, first difference set of the multi-channel signals between the first initial set of the multi-channel signals and the golden set of multi-channel signals, second difference set of the multi-channel signals between the second initial set of the multi-channel signals and the golden set of multi-channel signals, and third difference set of the multi-channel signals between the second initial set of the multi-channel signals and the golden set of multi-channel signals can also be used as training parameters for training a model along with the first to third shift vectors, the first to third tilt angles.

The method M1 proceeds to step S14, where a semiconductor substrate W is placed onto the substrate stage 150. The controller 190 may optionally control a shift and tilt status of the substrate stage 150 to receive the semiconductor substrate W. After the semiconductor substrate W is placed on the substrate stage 150, the controller 190 may optionally adjust the shift and tilt of the substrate stage 150 for an exposure position.

The method M1 proceeds to step S15, where the controller 190 may control the light sensing device 174 to detect a set of multi-channel signals. Then, the method M1 proceeds to step S16, where the controller 190 may determine if the detected set of multi-channel signals is acceptable based on the model. For example, based on the model, using the detected set of multi-channel signals as input parameters, output values, such as an output shift vector and an output tilt angle, can be obtained. By the model, the output shift vector may have a precision in a range from about 0.3 to about 0.7 nanometers in a vertical direction, such as about 0.5 nanometer in the vertical direction. And, by the model, the output tilt angle may have a precision in a range from about 0.7 micro radian to about 1.3 micro radian, such as about 1 micro radian.

At step S16, if an output shift vector is not acceptable (e.g., out of an acceptable range, such as a range from about −10 micrometers to about +10 micrometers in direction X/Y) and/or an output tilt angle is not acceptable (e.g., out of an acceptable range, such as a range from about −10 degrees to about +10 degrees), the method M1 proceeds to the step S17. At step S17, the controller 190 may adjust the shifts and the tilts of the substrate stage 150 based on the set of multi-channel signals and the model. For example, the controller 190 may adjust a position of the substrate stage 150 according to the output shift vector obtained by using the detected set of multi-channel signals as input parameters based on the model. And, the controller 190 may adjust a tilt angle of the substrate stage 150 according to the output tilt angle obtained by using the detected set of multi-channel signals as input parameters based on the model. Then, the method M1 may go back to the step S15. The steps S15, S16, and S17 are repeated until the output shift vector and an output tilt angle are acceptable.

At step S16, if an output shift vector is acceptable (e.g., within the acceptable range, such as a range from about −10 micrometers to about +10 micrometers in direction X/Y) and an output tilt angle is acceptable (e.g., within the acceptable range, such as the range from about −10 degrees to about +10 degrees), the method M1 proceeds to the step S18. At step S18, a lithography process is performed on the semiconductor substrate W. The exposure light EL is directed from the mask 130 to the semiconductor substrate W, thereby exposing a resist layer on the semiconductor substrate W.

After the lithography process, the method M11 proceeds to the step S19, wherein the semiconductor substrate W is moved away from the substrate stage 150. Then, the method M11 may go back to the step S14 to place another semiconductor substrate W on the substrate stage 150 for next lithography process. In some embodiments, the steps S11-S13 may be performed one time before plural exposure processes performed on plural semiconductor substrate W, while the S14-S19 are repeated for each semiconductor substrate W. The steps S11-S13 may be performed when the substrate stage 150 is absent from the semiconductor substrate W.

FIG. 10 is a method M2 for wafer stage alignment in a lithography apparatus 100. Reference is made to FIG. 10 and FIGS. 1A and 1B. The method M2 may include step S21-S29. It is understood that additional steps may be provided before, during, and after the steps S21-S29 shown by FIG. 10, and some of the steps described below can be replaced or eliminated for additional embodiments of the method. The order of the operations/processes may be interchangeable.

The method M2 begins at step S21, where the controller 190 may control/move the substrate stage 150 to be well aligned, such that that the surface of the substrate stage 150 is substantially parallel with the plane of the direction X and Y, and the substrate stage 150 is located at an ideal exposure position.

The method M2 proceeds to step S22, where the controller 190 may determine threshold shift vectors and threshold tilt angles of the substrate stage 150. For example, the threshold shift vectors may be about ±10 micrometers in directions X and Y. And, the threshold tilt angles may be about ±10 degrees.

The method M2 proceeds to step S23, where the controller 190 may adjust the substrate stage 150 to the threshold shift vectors and the threshold tilt angles. For example, the surface of the substrate stage 150 is tilted with respect to the plane of the direction X and Y by the threshold tilt angles and the substrate stage 150 is shifted from the ideal exposure position by the threshold shift vectors. At these threshold shift vectors and these threshold tilt angles, the controller 190 may control the light sensing device 174 to detect sets of multi-channel signal, which are referred to as sets of the threshold multi-channel signals hereinafter. The sets of the threshold multi-channel signals may provide lower limits and upper limits for acceptable ranges for various channel signals. For example, each channel has a lower limit, which is the minimum light intensity of the channel in the sets of the threshold multi-channel signals, and an upper limit, which is the maximum light intensity of the channel in the sets of the threshold multi-channel signals. The lower limit and the upper limit may define a acceptable range where the substrate W is considered as well aligned (e.g., the surface of the substrate stage 150 is substantially parallel with the plane of the direction X and Y, and the substrate stage 150 is located at an ideal exposure position).

The method M2 proceeds to step S24, where a semiconductor substrate W is placed onto the substrate stage. The controller 190 may optionally control a shift and tilt status of the substrate stage 150 to receive the semiconductor substrate W. After the semiconductor substrate W is placed on the substrate stage 150, the controller 190 may optionally adjust the shift and tilt of the substrate stage 150 for an exposure position.

The method M2 proceeds to step S25, the controller 190 may control the light sensing device 174 to detect a set of multi-channel signals. Then, the method M1 proceeds to step S26, where the controller 190 may determine if the detected set of multi-channel signals is in the acceptable ranges defined by the sets of the threshold multi-channel signals.

At step S26, if the detected set of multi-channel signals is not in the range defined by the sets of the threshold multi-channel signals, the method M1 proceeds to the step S27. At step S27, the controller 190 may adjust the shifts and the tilts of the substrate stage 150 based on the set of multi-channel signals and the sets of the threshold multi-channel signals. For example, the controller 190 may adjust a position of the substrate stage 150 and/or a tilt angle of the substrate stage 150 according to a difference between the set of multi-channel signals and the sets of the threshold multi-channel signals. Then, the method M1 may go back to the step S25. The steps S25, S26, and S27 are repeated until the detected set of multi-channel signals is in the range defined by the sets of the threshold multi-channel signals.

At step S26, if the detected set of multi-channel signals is in the range defined by the sets of the threshold multi-channel signals, the method M1 proceeds to the step S28. At step S28, a lithography process is performed on the semiconductor substrate W. The exposure light EL is directed from the mask 130 to the semiconductor substrate W, thereby exposing a resist layer on the semiconductor substrate W.

After the lithography process, the method M21 proceeds to the step S29, wherein the semiconductor substrate W is moved away from the substrate stage 150. Then, the method M21 may go back to the step S24 to place another semiconductor substrate W on the substrate stage 150 for next lithography process. In some embodiments, the steps S21-S23 may be performed one time before plural exposure processes performed on plural semiconductor substrate W, while the S24-S29 are repeated for each semiconductor substrate W. The steps S21-S23 may be performed when the substrate stage 150 is absent from the semiconductor substrate W.

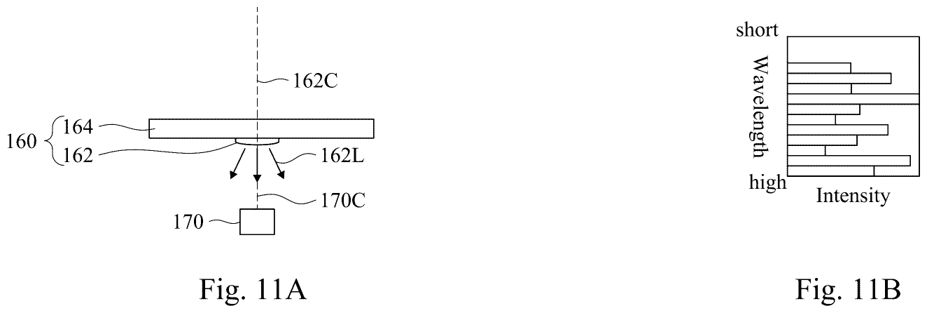

FIG. 11A shows an inspection condition according to some embodiments of the present disclosure. FIG. 11B is a result of the inspection condition of FIG. 11A. In the present embodiments, the optical axis 162C of the light source 162 is aligned with a center line 170C of the light receiver structure 170. In the present embodiments, the light detected by the light receiver structure 170 have a high intensity in different color channels, which means that the position of the substrate stage 150 is correct.

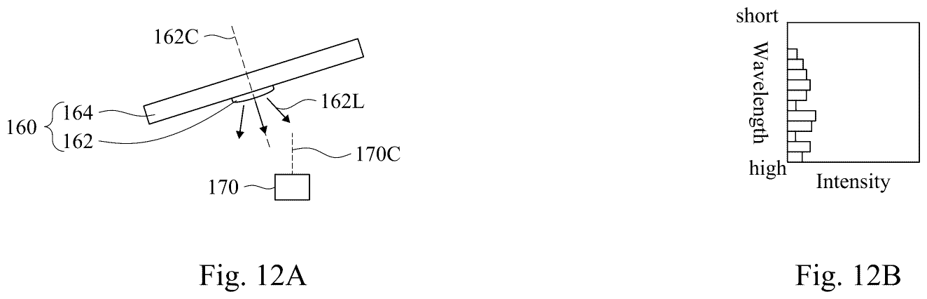

FIG. 12A shows an inspection condition according to some embodiments of the present disclosure. FIG. 12B is a result of the inspection condition of FIG. 12A. The optical axis 162C of the light source 162 is left-side tilted with respect to a center line 170C of the light receiver structure 170. In the present embodiments, the light detected by the light receiver structure 170 have a low intensity in all the various color channels, which indicates a tilt of the substrate stage 150.

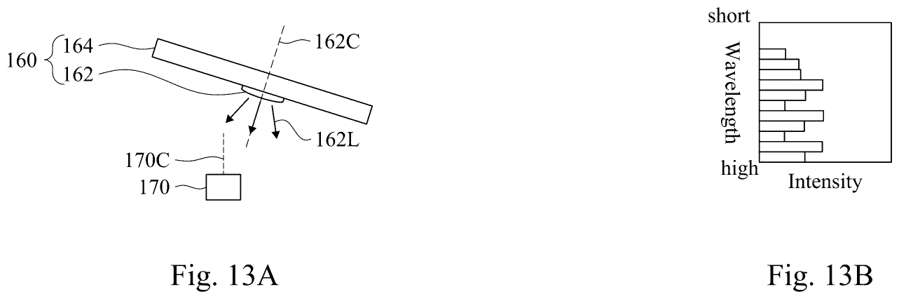

FIG. 13A shows an inspection condition according to some embodiments of the present disclosure. FIG. 13B is a result of the inspection condition of FIG. 13A. The optical axis 162C of the light source 162 is right-side tilted with respect to a center line 170C of the light receiver structure 170. In the present embodiments, the light detected by the light receiver structure 170 have a low intensity in almost all the various color channels, which indicates a tilt of the substrate stage 150.

In some cases, the light detected by the light receiver structure 170 have a low intensity in some of the various color channels, but a high intensity in the others of the various color channels. This detection result may indicate a shift of the substrate stage 150.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that an alignment status can be verified and determined to be correct or not by using the light receiver structure over a substrate stage. Another advantage is that a process duration for alignment is reduced by using the light receiver structure over the substrate stage. Still another advantage is that the number of marks is reduced, and the scanning time is shortened. Still another advantage is that better resolution can be achieved by adjusting the slit width.

According to some embodiments of the present disclosure, a lithography apparatus includes a substrate stage having a first region configured to hold a semiconductor substrate and a second region surrounding the first region; a light receiver structure over the second region of the substrate stage; a light source configured to provide an alignment light toward the second region of the substrate stage; a mask stage configured to secure a mask; and an optical module configured to direct an exposure light from the mask onto the semiconductor substrate.

According to some embodiments of the present disclosure, a lithography apparatus includes a substrate stage configured to hold a semiconductor substrate; a light receiver structure over the substrate stage, wherein the light receiver structure comprises: a photosensitive device layer comprising a plurality of photosensitive pixels; and a color filter layer having a plurality of portions respectively over the photosensitive pixels, wherein the portions of the color filter layer have different transmittance spectrums; a mask stage configured to secure a mask; and an optical module configured to direct an exposure light from the mask onto the semiconductor substrate.

According to some embodiments of the present disclosure, a method for operating a lithography apparatus is provided. The method includes placing a semiconductor substrate over a first region of a substrate stage; directing an alignment light to a second region of the substrate stage; using a light receiver structure over the second region of the substrate stage, detecting a plurality of different wavelengths of light; after detecting the different wavelengths of light, directing an exposure light to the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography apparatus, comprising:
a substrate stage having a first region configured to hold a semiconductor substrate and a second region surrounding the first region;
a light receiver structure over the second region of the substrate stage;
a light source configured to provide an alignment light toward the second region of the substrate stage;
a mask stage configured to secure a mask; and
an optical module configured to direct an exposure light from the mask onto the semiconductor substrate.

2. The lithography apparatus of claim 1, wherein the exposure light is directed onto the semiconductor substrate along a first direction, and the alignment light is provided toward the second region of the substrate stage along a second direction substantially parallel with the first direction.

3. The lithography apparatus of claim 1, wherein the light receiver structure comprises:
a photosensitive device layer comprising a plurality of photosensitive pixels; and
a color filter layer having a plurality of portions respectively over the photosensitive pixels, wherein the portions of the color filter layer have different transmittance spectrums.

4. The lithography apparatus of claim 3, wherein the light receiver structure further comprises:
a shell surrounding the photosensitive device layer and the color filter layer, wherein the shell has an opening facing away from the substrate stage.

5. The lithography apparatus of claim 3, wherein the photosensitive pixels of the photosensitive device layer are arranged along a plane substantially parallel with a top surface of the substrate stage.

6. The lithography apparatus of claim 1, wherein a peak wavelength of the alignment light is different from a peak wavelength of the exposure light.

7. The lithography apparatus of claim 1, wherein the light source comprises a broadband light source.

8. The lithography apparatus of claim 1, further comprising:
a wall surrounding the substrate stage, the light receiver structure, the light source, the mask stage, and the optical module.

9. A lithography apparatus, comprising:
a substrate stage configured to hold a semiconductor substrate;
a light receiver structure over the substrate stage, wherein the light receiver structure comprises:
a photosensitive device layer comprising a plurality of photosensitive pixels; and
a color filter layer having a plurality of portions respectively over the photosensitive pixels, wherein the portions of the color filter layer have different transmittance spectrums;
a mask stage configured to secure a mask; and
an optical module configured to direct an exposure light from the mask onto the semiconductor substrate.

10. The lithography apparatus of claim 9, wherein the light receiver structure further comprises:
a light shielding plate over the color filter layer, wherein the light shielding plate has an opening exposing the color filter layer.

11. The lithography apparatus of claim 10, wherein the light receiver structure further comprises:
a light shielding box surrounding the color filter layer and the photosensitive device layer, wherein the light shielding box has an opening exposing the color filter layer.

12. The lithography apparatus of claim 9, wherein the photosensitive pixels of the photosensitive device layer are arranged along a plane substantially parallel with a top surface of the substrate stage.

13. The lithography apparatus of claim 9, further comprising:
a wall surrounding the substrate stage, the light receiver structure, the mask stage, and the optical module.

14. The lithography apparatus of claim 9, wherein the color filter layer is a linear variable color filter.

15. A method for operating a lithography apparatus, comprising:
placing a semiconductor substrate over a first region of a substrate stage;
directing an alignment light to a second region of the substrate stage;
using a light receiver structure over the second region of the substrate stage, detecting a plurality of different wavelengths of light; and
after detecting the different wavelengths of light, directing an exposure light to the semiconductor substrate.

16. The method of claim 15, wherein directing the alignment light to the second region of the substrate stage is performed along a first direction, and directing the exposure light to the semiconductor substrate is performed along a second direction substantially parallel with the first direction.

17. The method of claim 15, further comprising:
determining whether a tilt of the substrate stage is acceptable based on a result of detecting the alignment light; and
in response the determination determines that the tilt of the substrate stage is not acceptable, adjusting a position and a tilt angle of the substrate stage, wherein directing the exposure light to the semiconductor substrate is performed in response the determination determines that the tilt of the substrate stage is acceptable.

18. The method of claim 15, further comprising:
determining whether a position of the substrate stage is acceptable based on a result of detecting the alignment light; and
in response the determination determines that the position of the substrate stage is not acceptable, adjusting a position of the substrate stage, wherein directing the exposure light to the semiconductor substrate is performed in response the determination determines that the position of the substrate stage is acceptable.

19. The method of claim 15, wherein a peak wavelength of the alignment light is different from a peak wavelength of the exposure light.

20. The method of claim 15, wherein the different wavelengths of light are longer than a peak wavelength of the exposure light.
